(19) United States
(12) Patent Application Publication
(10) Pub. No.: US 2011/0164336 A1
(43) Pub. Date: Jul. 7, 2011

(54) PATTERNED MEDIA AND FABRICATION METHOD THEREOF

(75) Inventors: Yoshiyuki Hirayama, Kokubunji (JP); Masayoshi Shimizu, Chigasaki (JP); Taku Iwase, Odawara (JP)

(73) Assignee: Hitachi, Ltd.

(21) Appl. No.: 12/984,352

(22) Filed: Jan. 4, 2011

(30) Foreign Application Priority Data
Jan. 5, 2010 (JP) 2010-000619

(51) Int. Cl. G11B 5/82; B05D 5/12; C23C 14/00

(52) U.S. Cl. 360/135; 427/523; G9B/5.293

(57) ABSTRACT

Since the surface roughness of a recording layer get larger in the process of fabricating a patterned medium, the spacing between a head and the medium is widened. As a result, the recording performance and corrosion resistance of the medium are degraded. In the patterned medium, a recording layer includes one layer of a crystalline magnetic film or plural layers of crystalline magnetic films, and a magnetic film of an amorphous structure located on the outermost surface of the crystalline magnetic films. The compositional elements of the magnetic film of the amorphous structure are identical to those of the crystalline magnetic film located immediately under the magnetic film. In a fabrication method thereof, the surface of the crystalline magnetic film is turned into amorphous in order to form the magnetic film of the amorphous structure.

### CLAIM OF PRIORITY

The present application claims priority from Japanese patent application JP 2010-000619 filed on Jan. 5, 2010, the content of which is hereby incorporated by reference into this application.

### BACKGROUND OF THE INVENTION

1. Field of the Invention

The present invention relates to patterned media employed in hard disk drives and a fabrication method thereof. In particular, the present invention is concerned with patterned media that can be readily fabricated and are superb in recording performance and reliability.

2. Description of the Related Art

Along with an increase in an amount of information in the world, there is an impending demand for an increase in the storage capacity of storage equipment in which the information is recorded. In particular, a hard disk drive is not only used to preserve data for a personal computer or a server but also mounted in a television set, a video recorder, a camera, or an automotive navigation system. The hard disk drive has the application range thereof expanded and is expected to offer a larger storage capacity.

In order to increase the storage capacity of the hard disk drive, that is, the recording density thereof, mere improvement of an existing perpendicular magnetic recording scheme is thought to be confronted with limitations. As a technology for breaking through the limitations, discrete track media or bit-patterned media (generically called patterned media) are under research and development. The discrete track media make it possible to upgrade a track density by separating adjacent recording tracks from each other with a nonmagnetic material so as to reduce a magnetic interaction between the adjacent tracks. The bit-patterned media make it possible to increase a recording density by artificially regularly arranging small magnetic grains that are separated from one another with the nonmagnetic material. In either case, a nano-engineering technology for arraying a magnetic material and the nonmagnetic material on a plane is necessary.

For fabrication of patterned media, a magnetic film is processed through etching. A fabrication method of the patterned media is described in, for example, Japanese Patent Application Laid-Open Publication No. 2001-110050. For the patterned media, a reactive gas is employed in etching and the surface area of the magnetic film increases. Therefore, there is a high risk that the magnetic film may be corroded. Sufficient measures have to be taken for corrosion resistance.

As a magnetic film material to be adopted for patterned media, a cobalt chromium platinum-silicon dioxide (CoCrPt—SiO₂) alloy employed in existing perpendicular magnetic recording media, or an iron platinum (FePt) ordered alloy or a cobalt platinum (CoPt) ordered alloy that exerts large magnetic anisotropy energy has been discussed. The crystalline magnetic film materials are suitable for high-density recording because of the large crystalline magnetic anisotropy energy. As a magnetic material exerting large magnetic anisotropy energy, aside from the crystalline magnetic film materials, there is an alloy having as a major component a rare-earth transition metal, such as, a terbium iron cobalt (TbFeCo) alloy. For example, Japanese Patent Application Laid-Open Publication No. 2001-84546 describes that the alloy having the rare-earth transition metal as a major component is employed in magnetic recording media. However, the alloy having the rare-earth transition metal as a major component is poor in corrosion resistance, it cannot be applied to the patterned media.

### SUMMARY OF THE INVENTION

In order to ensure high recording performance for a patterned medium, it is necessary to obtain stable flying of a head and minimize the spacing between the head and medium. A nonmagnetic material has to be buried in grooves, which are created by cutting out a magnetic film through etching, in order to finally produce a smooth surface. If an excess nonmagnetic material remains on the surface of the magnetic film, the spacing between the head and medium gets wider. This invites degradation in recording performance.

FIG. 4A and FIG. 4B are schematic sectional views showing a difference in the spacing between a head and a medium. FIG. 4A is concerned with a case where the surface roughness of a magnetic film of the medium is large, while FIG. 4B is concerned with a case where the roughness is small. As seen from the drawings, even when control is extended to keep a flying height 131 of the head 130 constant, if the surface roughness of the magnetic film of the medium 100 is large, the spacing 132 between the head 130 and medium 100 is widened. In other words, the flying height 131 is determined with the shortest distance between (the top end of a convex part of) the medium 100 and head 130. The spacing 132 is regarded as a distance over which a recording layer functions as it is (a height obtained by averaging the heights of the convex parts). Therefore, the larger the roughness is, the wider the spacing is. How smoothly the surface of a medium is finished is a significant issue concerning patterned media.

As mentioned above, problems to be addressed are that the recording performance of a patterned medium is degraded because the spacing between a head and the medium is widened as a result of an increase in the surface roughness of a recording layer occurring in the process of fabricating the patterned medium, and that corrosion resistance is degraded because it becomes hard to coat the recording layer with a thin protective film due to the increase in the surface roughness.

An object of the present invention is to provide patterned media that make it possible to decrease the spacing between a head and a medium and are superior in corrosion resistance, and a fabrication method thereof.

As an embodiment for accomplishing the above object, there is provided a patterned medium characterized in that a recording layer of the patterned medium includes one layer of a crystalline magnetic film or plural layers of crystalline magnetic films, and a magnetic film of an amorphous structure located on the outermost surface of the crystalline magnetic films, and that the compositional elements of the magnetic film of the amorphous structure are identical to the compositional elements of the crystalline magnetic film located immediately under it.

A fabrication method of the patterned medium is characterized in that the surface of the magnetic film of the crystalline structure is turned into amorphous by irradiating ions to the outermost surface of the crystalline magnetic films.

Owing to the foregoing construction, the surface roughness of a recording layer are reduced, the spacing between a head and a medium is decreased, and excellent recording performance is exerted. Further, a patterned medium exhibiting excellent corrosion resistance can be provided. In addition, there is provided a fabrication method of the patterned medium making it possible to readily fabricate the patterned medium without the necessity of adding a novel material in order to gain the advantages.

### BRIEF DESCRIPTION OF THE DRAWINGS

FIG. 1 is a schematic sectional view showing the structure of a patterned medium in accordance with a first embodiment;

FIGS. 2A to 2G are schematic sectional views showing the structure of the patterned medium in accordance with the first embodiment so as to present a fabrication process, FIG. 2A shows a resist pattern formation step, FIG. 2B shows a step of transferring a resist pattern to a protective film, FIG. 2C shows a step of transferring the resist pattern to a recording layer, FIG. 2D shows a step of removing the resist pattern and protective film, FIG. 2E shows a step of etching a backfilling film, FIG. 2F shows a step of forming an amorphous magnetic film by making the surface of the recording layer amorphous, and FIG. 2G shows a step of forming the protective film;

FIG. 3 includes a schematic plan view showing the whole of a discrete track medium, and a schematic plan view showing part of the discrete track medium in enlargement; and

FIGS. 4A and 4B are schematic sectional views showing a difference in the spacing between a head and a medium, FIG. 4A is concerned with a case where the surface roughness of a magnetic film is large, and FIG. 4B is concerned with a case where the roughness is small.

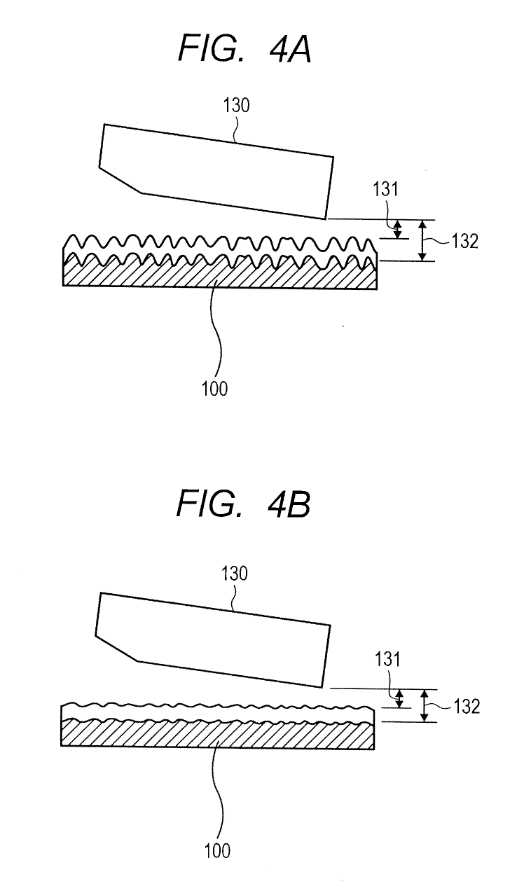

### DESCRIPTION OF THE PREFERRED EMBODIMENTS

A description will be made below by citing embodiments.

### First Embodiment

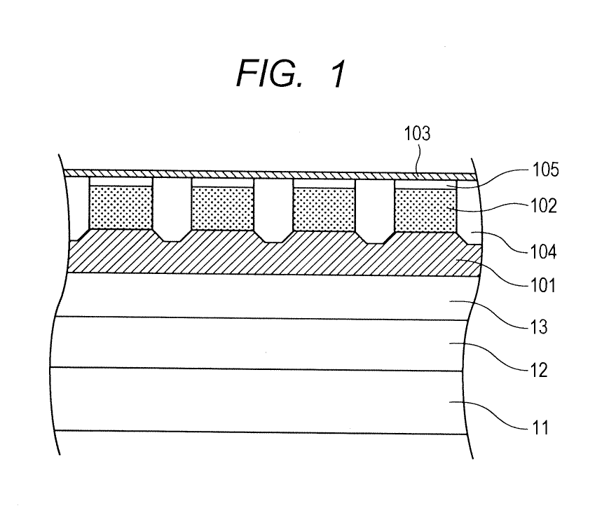

A first embodiment will be described below in conjunction with FIG. 1 to FIG. 3. FIG. 1 is a schematic sectional view showing the structure of a patterned medium in accordance with the present embodiment. The patterned medium includes a backfilling film 104 formed on a film having a substrate 11, a soft magnetic underlayer 12, a seed layer 13, and an orientation control underlayer 101 sequentially layered thereon, a recording layer (a crystalline magnetic film 102 whose surface is turned into amorphous) separated into portions with the backfilling film 104, and a protective film 103 formed on the recording layer. Reference numeral 105 denotes an amorphous magnetic film that is the surface of the crystalline magnetic film 102 turned into amorphous.

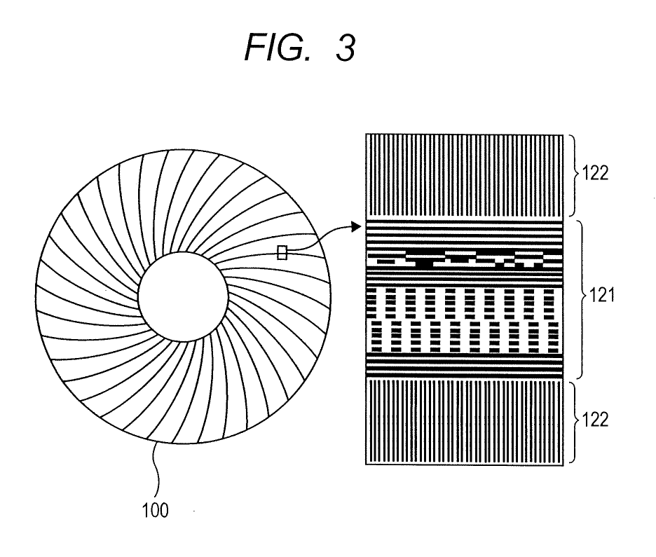

FIG. 3 includes a schematic plan view showing the whole of a discrete track medium and a schematic plan view showing part of the discrete track medium in enlargement. A discrete track medium 100 includes servo pattern regions 121 each having a pattern, which is necessary to position a head, formed therein, and discrete track regions 122 in which information is recorded.

In relation to the present embodiment, a fabrication method of a discrete track medium having the structure shown in FIG. 1 and the properties thereof will be described below.

A medium serving as a base of a discrete track medium was formed using a sputtering method. An iron cobalt tantalum zirconium (FeCoTaZr) alloy film of 50 nm thick serving as the soft magnetic underlayer 12, a nickel tantalum (NiTa) alloy film of 10 nm thick serving as the seed layer 13, a ruthenium (Ru) film of 20 nm thick serving as the orientation control underlayer 101, a cobalt chromium platinum-silicon dioxide (CoCrPt—SiO₂) alloy film of 12 nm thick and a cobalt chromium platinum boron (CoCrPtB) alloy film of 5 nm thick serving as the recording layer, and a nitrogen-containing carbon film of 2.5 nm thick serving as the protective layer 103 were sequentially formed on a glass substrate 11 of 65 mm in diameter, whereby a base medium was produced.

After particles adhering to the surface of the base medium were washed down through pure water washing, a resist pattern was formed on the surface of the base medium using a nano-imprint method. Nano-imprint was performed by impressing a low-viscosity resist, which is applied to the surface of the base medium, with a quartz-made mold so as to form a pattern, and irradiating ultraviolet rays so as to harden the resist. The resist pattern may be formed using a photolithography method. However, the nano-imprint method is advantageous in terms of a cost of fabrication.

The resist pattern includes discrete track regions 122 having a track pitch of 76 nm, and servo pattern regions 121 (FIG. 3). The resist film thickness of an upper part of the resist pattern was 60 nm, and the resist film thickness of a bottom portion thereof was 10 nm.

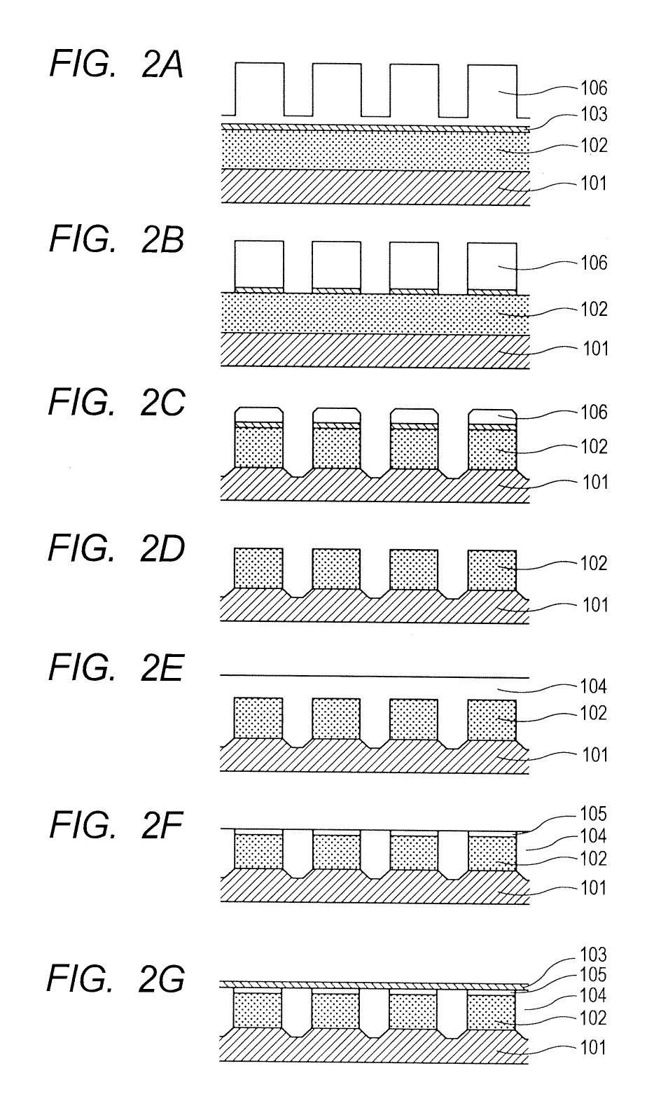

A fabrication method will be described in conjunction with FIG. 2A to FIG. 2G. FIG. 2A to FIG. 2G are schematic sectional views showing the structure of the discrete track medium in accordance with the present embodiment so as to present a fabrication process of the discrete track medium. In the drawings, an under-layer portion of the discrete track medium including the seed layer 13 is not shown.

Through nano-imprint, a concavo-convex pattern 106 of a resist like the one shown in FIG. 2A is formed on the surface of the base medium. To begin with, a residual resist film left on the bottoms of concave parts of the imprinted resist was removed by performing reactive ion etching with oxygen. At the same time, the carbon protective film 103 formed on the surface of the recording layer 102 was also removed. This results in a sectional structure shown in FIG. 2B. The reactive ion etching was performed using inductively coupled plasma for a processing time of 10 sec under the conditions that an oxygen flow rate was 30 sccm, a gas pressure was 0.6 Pa, and a power was 50 W.

Thereafter, the resist pattern 106 was transferred to the recording layer 102. The recording layer 102 including the CoCrPtB alloy film and CoCrPt—SiO₂ alloy film was cut out through ion beam etching with argon. The ion beam etching was performed using an electron cyclotron resonance (ECR) ion source for a processing time of 12 sec under the conditions that an acceleration voltage was 300 V and a beam incident angle was a perpendicular with respect to the film surface. When the orientation control underlayer 101 was slightly cut out, the etching was ceased in order to obtain a sectional structure shown in FIG. 2C.

The resist pattern 106 and carbon protective film 103 left on the surface of the recording layer were removed through reactive ion etching with hydrogen, whereby a sectional structure shown in FIG. 2D was obtained. The reactive ion etching was performed using inductively coupled plasma for a processing time of 30 sec under the conditions that a hydrogen flow rate was 50 sccm, a gas pressure was 5 Pa, and a power was 250 W.

Thereafter, the carbon film (backfilling film) 104 made of a nonmagnetic material and having a thickness of approximately 30 nm was formed using a sputtering method in order to backfill grooves created in the magnetic film. The carbon film was etched back and planarized by sputter etching with argon. For the sputter etching, inductively coupled plasma was used and a power of 300 W was fed. When the thickness of the carbon film became approximately 10 nm, the sputter etching is ceased and switched to ion beam etching with argon.

Etching back was carried on until the state shown in FIG. 2E proceeded to a state in which the recording layer finally comes out to the surface of the medium as shown in FIG. 2F. At that time, overetching occurred by a time it takes to cut out the CoCrPtB alloy film of approximately 1 nm thick. For ion beam etching, an ECR ion source was used, an acceleration voltage is set to 500 V, and a beam incident angle was set to a perpendicular with respect to the film surface. The surface of the recording layer is turned into amorphous due to overetching caused by an argon ion beam, whereby the amorphous magnetic film 105 is formed. A film thickness to be turned into amorphous can be controlled by modifying conditions for overetching.

Finally, a nitrogen-containing carbon film of 2.5 nm thick was formed as the protective film 103 using a sputtering method, and the resultant medium was taken out of a vacuum chamber (FIG. 2G). A lubrication film of 1 nm thick was applied to the surface of the protective film, and tape cleaning was carried out in order to finish the discrete track medium.

In order to check the structure of the fabricated discrete track medium, the section of the discrete track medium was observed using a high-resolution transmission electron microscope. The laminated construction of the section was almost as shown in FIG. 1. The Ru orientation control underlayer 101 was seen to have a c-axis of a close-packed hexagonal lattice thereof formed with columnar grains, which were oriented perpendicularly to the film surface, and the crystalline magnetic film (recording layer) 102 made of a CoCrPt alloy was seen to have a c-axis of a close-packed hexagonal lattice thereof grown as columnar grains oriented perpendicularly to the film surface. Further, the amorphous magnetic film 105 of 1.2 nm thick was seen to be produced on the crystalline magnetic film. The amorphous carbon backfilling film 104 was seen to exist among the discrete tracks formed on the magnetic film, and the carbon protective film 103 was seen to be nearly flatly formed on the surface of the medium. The land width of discrete tracks was approximately 50 nm.

The superficial shape of the medium was evaluated using an atomic force microscope (AFM). The average roughness (Ra) obtained by scanning the discrete track region with a visual field of 1 μm was 0.45 nm, whereby it was verified that a smooth surface was produced.

Thereafter, a spin-stand tester was used to evaluate recording and reproduction performances. After it was verified that any of the data tracks could be followed based on a signal acquired from any of the servo patterns produced through etching, a signal-to-noise ratio on the track was evaluated. The recording width of a head employed in the evaluation was 65 nm, and the reproduction width thereof was 55 nm. The spacing between the head and medium was controlled so that the head was located at a position withdrawn by 1 nm from a point at which the contact of the head with the medium was sensed. When a signal offering a linear recording density of 1500 kbpi was recorded on the discrete tracks whose track pitch was 76 nm, the signal-to-noise ratio was 14.8 dB.

Further, a corrosion resistance test was conducted on the discrete track medium. After, the medium was left intact for 96 hours in an atmosphere of 80° C. in temperature and 90% in humidity, the number of corroded points was counted and regarded as an index of corrosion resistance. The number of corroded points in the medium of the present embodiment was three per square centimeter (cm²). This verifies that the medium is superior in corrosion resistance.

As mentioned above, according to the present embodiment, when an amorphous magnetic film having the same compositional elements as the compositional elements of a crystalline magnetic film serving as a recording layer is formed on the crystalline magnetic film, the spacing between a head and a medium can be minimized. Eventually, a patterned medium superior in corrosion resistance and a fabrication method thereof can be provided.

### First Comparative Example

A discrete track medium of the present comparative example was fabricated using the nearly same base medium as that of the first embodiment. A sole difference from the base medium employed in the first embodiment lies in that the thickness of a CoCrPtB alloy film of a recording layer is set to 4 nm.

For processing a medium, nearly the same process as that employed in the first embodiment was adopted. A sole difference lies in that reactive ion etching with hydrogen is substituted for ion beam etching with argon in order to finish etching back of carbon that is used as a backfill. The reactive ion etching was performed using inductively coupled plasma under the conditions that a hydrogen flow rate was 30 sccm, a gas pressure was 0.6 Pa, and a power was 50 W. The employment of hydrogen makes it possible to prevent oxidation of the surface of the recording layer, and to minimize a physical damage to the recording layer. The reactive ion etching was ceased without overetching of a CoCrPtB alloy film. Namely, the final thickness of the CoCrPtB alloy film was 4 nm or identical to that in the first embodiment. Finally, a nitride-containing carbon film of 2.5 nm thick was formed as a protective film, a lubrication film of 1 nm thick was applied to the surface of the protective film, and tape cleaning was carried out.

The fabricated discrete track medium was evaluated using the same method as that in the first embodiment. The section of the medium was observed using a high-resolution transmission electron microscope. A crystalline magnetic film of a CoCrPt apply was, similarly to that in the first embodiment, seen to have a c-axis of a close-packed hexagonal lattice thereof grown as columnar grains oriented perpendicularly to the film surface. However, an amorphous magnetic film did not exist on the crystalline magnetic film, but a carbon protective film was directly layered on the crystalline magnetic film.

The superficial shape of the medium was evaluated using an atomic force microscope (AFM). The average roughness (Ra) obtained by scanning the surface of the medium with a visual field of 1 μm was 1.55 nm. Compared with the first embodiment, the surface roughness was found to have increased.

A spin-stand tester was used to evaluate recording and reproduction performances. A signal-to-noise ratio detected when a signal offering a linear recording density of 1500 kbpi was recorded in any of data tracks having a track pitch of 76 nm was 12.1 dB. Conceivably, since the spacing between the head and medium was widened due to an increase in the surface roughness of the medium, the signal-to-noise ratio decreased.

Further, a corrosion resistance test was conducted. The number of corroded points on the medium of the present comparative example was 122 per square centimeter (cm²). This demonstrates that compared with the first embodiment, the present comparative example is inferior in corrosion resistance. Since the coating ability of the carbon protective film becomes insufficient because of an increase in the surface roughness of the recording layer, and the surface of the recording layer is inhomogeneous, corrosion is presumably likely to occur.

### Second Comparative Example

A discrete track medium of the present comparative example was fabricated using a base medium nearly identical to that employed in the first embodiment. A sole difference from the base medium employed in the first embodiment lies in that a CoTaZr amorphous alloy film of 2.8 nm thick was layered on a CoCrPt—SiO₂ alloy film of 12 nm thick in order to produce a recording layer.

For processing of the medium, the same process as that in the first comparative example was adopted. Specifically, reactive ion etching with hydrogen was substituted for ion beam etching with argon in order to finish etching back of carbon that was used as a backfill. Finally, a nitride-containing carbon film of 2.5 nm thick was formed as a protective film, a lubrication film of 1 nm thick was applied to the surface of the protective film, and tape cleaning was carried out.

The fabricated discrete track medium was evaluated using the same method as that employed in the first embodiment. The section of the medium was observed using a high-resolution transmission electron microscope. A crystalline magnetic film of a CoCrPt alloy was, similarly to that in the first embodiment, seen to have a c-axis of a close-packed hexagonal lattice thereof grown as columnar grains oriented perpendicularly to the film surface. A CoTaZr amorphous magnetic film of 2.8 nm thick was seen to exist on the crystalline magnetic film.

The superficial shape of the medium was evaluated using an atomic force microscope (AFM). The average roughness (Ra) obtained by scanning the medium with a visual field of 1 μm was 0.67 nm. Production of a relatively smooth surface was verified.

A spin-stand tester was used to evaluate recording and reproduction performances. A signal-to-noise ratio obtained when a signal offering a linear recording density of 1500 kbpi was recorded on data tracks having a track pitch of 76 nm was 13.7 dB.

Further, a corrosion resistance test was conducted. The number of corroded points on the medium of the present comparative example was 109 per square centimeter (cm²). This demonstrates that compared with the first embodiment, the present comparative example is inferior in corrosion resistance. The surface roughness of the recording layer is not as large as that in the first embodiment. Conceivably, since magnetic films that are different from each other in terms of compositional elements are layered, an electric potential is generated between the magnetic films. This presumably facilitates corrosion. For improvement of the corrosion resistance, not only the structure of a magnetic film to be layered near the surface of the medium but also a combination of compositional elements has significant meanings.

### Second Embodiment

A second embodiment will be described below. The items that have been described in relation to the first embodiment but will not be described in relation to the present embodiment can be applied to the present embodiment.

In relation to the present embodiment, a fabrication method different from the one of the first embodiment that is the discrete track medium having the structure shown in FIG. 1, and the properties thereof will be described below.

A medium serving as a base of a discrete track medium was formed using a sputtering method. An FeCoTaZr alloy film of 40 nm thick serving as a soft magnetic underlayer 12, an NiTa alloy film of 10 nm thick serving as a seed layer 13, an Ru film of 20 nm thick serving as an orientation control underlayer 101, a CoCrPt—SiO2 alloy film of 13 nm thick and a CoCrPtB alloy film of 6.5 nm thick serving as a recording layer, and a nitrogen-containing carbon film of 2.5 nm thick serving as a protective film 103 were sequentially formed on a glass substrate 11 of 65 mm in diameter in order to produce a base medium.

Particles adhering to the surface of the base medium were washed down through pure water washing, and a resist pattern 106 was formed on the surface of the base medium using a nano-imprint method. Nano-imprint was performed by depressing a low-viscosity resist, which was applied to the surface of the base medium, with a quartz-made mold so as to form a pattern, and irradiating ultraviolet rays so as to harden the resist.

The resist pattern 106 includes a region of discrete tracks having a track pitch of 68 nm and a region of servo patterns. The resist film thickness of an upper part of the resist pattern was 55 nm, and the resist film thickness of a bottom portion thereof was 9 nm.

A fabrication method will be described in conjunction with FIG. 2A to FIG. 2G. Nano-imprint and transfer of the resist pattern 106 to the recording layer are identical to those in the first embodiment. A resist remaining on the surface of the recording layer and the carbon protective film 103 were removed through reactive ion etching with oxygen in order to obtain a sectional structure shown in FIG. 2D. In the first embodiment, hydrogen is employed. Herein, the reactive ion etching with oxygen was used to remove the resist and carbon protective film 103 efficiently at a high speed. Inductively coupled plasma was used to perform the reactive ion etching for a processing time of 15 sec under the conditions that an oxygen flow rate was 50 sccm, a gas pressure was 5 Pa, and a power was 250 W. Noted is that an oxidation layer was formed on the surface of the recording layer.

Thereafter, a silicon nitride film of approximately 35 nm thick was formed using a sputtering method in order to backfill grooves formed in the magnetic film. The silicon nitride film was etched back and planarized by sputter etching with argon. The sputter etching was ceased when the thickness of the silicon nitride film became approximately 10 nm, and switched to reactive ion etching with carbon tetrafluoride (CF₄).

The etching back was carried on until the state shown in FIG. 2E proceeds to a state in which the recording layer comes out to the surface of the medium as shown in FIG. 2F. However, since the surface of the recording layer is oxidized, iron beam etching with argon is further performed in order to cut an oxidation layer out from the surface of the CoCrPtB alloy magnetic film. Further, the CoCrPtB alloy magnetic film was cut out a bit, and etching back was carried on until the thickness of the CoCrPtB alloy magnetic film became 4 nm at last. The ion beam etching was performed using an ECR ion source under the conditions that an acceleration voltage was 500 V and a beam incident angle was a perpendicular with respect to the film surface. Due to etching with an ion beam of argon, the surface of the CoCrPtB alloy magnetic film is turned into amorphous to form an amorphous magnetic film 105. A film thickness to be turned into amorphous can be controlled by modifying conditions for etching.

Finally, a nitride-containing carbon film of 2.5 nm thick was formed as a protective film 103 using a sputtering method, and the medium was taken out of a vacuum chamber (FIG. 2G). A lubrication film of 1 nm thick was applied to the surface of the protective film, and tape cleaning was performed in order to finish the discrete track medium.

The fabricated discrete track medium was evaluated by adopting the same method as that in the first embodiment. The section of the medium was observed using a high-resolution transmission electron microscope. The crystalline magnetic film (recording layer) 102 of a CoCrPt alloy was, similarly to that in the first embodiment, seen to have a c-axis of a close-packed hexagonal lattice thereof grown as columnar grains oriented perpendicularly to the film surface. In addition, the amorphous magnetic film 105 of approximately 1.4 nm thick was seen to be produced on the crystalline magnetic film. The amorphous silicon nitride backfilling film 104 was seen to exist among the discrete tracks formed on the processed magnetic film, and the carbon protective film 103 was seen to be nearly flatly formed on the surface of the medium.

The superficial shape of the medium was evaluated using an atomic force microscope (AFM). The average roughness (Ra) obtained by scanning the surface of the medium with a visual field of 1 μm was 0.41 nm. Production of a smooth surface was verified.

For evaluating recording and reproduction performances using a spin-stand tester, after it was verified that any of the data tracks could be followed based on a signal acquired from any of the servo patterns formed through etching, a signal-to-noise ratio on the track was evaluated. The recording width of a head used for the evaluation was 60 nm and the reproduction width thereof was 49 nm. The spacing between the head and medium was controlled so that the head was located at a position withdrawn by 1 nm from a point at which contact of the head with the medium was sensed. A signal-to-noise ratio detected when a signal offering a linear recording density of 1500 kbpi is recorded on any of the data tracks having a track pitch of 68 nm was 14.5 dB.

Further, a corrosion resistance test was conducted. Similarly to the first embodiment, after the medium was left intact for 96 hours in an atmosphere of 80° C. in temperature and 90% in humidity, the number of corroded points was counted and regarded as an index of corrosion resistance. The number of corroded points on the medium of the present embodiment was two per square centimeter (cm²). This demonstrates that the medium of the present embodiment is superior in corrosion resistance.

As mentioned above, according to the present embodiment, since an amorphous magnetic film having the same compositional elements as those of a crystalline magnetic film serving as a recording layer is formed on the crystalline magnetic film, the spacing between a head and a medium can be minimized. In addition, a patterned medium superior in corrosion resistance and a fabrication method thereof can be provided. When a resist pattern and a carbon protective film are etched using oxygen, these films can be removed at a high speed. Eventually, a throughput can be improved.

### Third Embodiment

In relation to the present embodiment, a fabrication method of a bit-patterned medium having the structure shown in FIG. 1, and the properties thereof will be described below. The items that have been described in relation to the first or second embodiment but will not be described in relation to the present embodiment can be applied to the present embodiment.

A medium serving as a base of a bit-patterned medium was formed using a sputtering method. A cobalt tantalum zirconium (CoTaZr) alloy film of 30 nm thick serving as a soft magnetic underlayer, a Ta film of 3 nm thick serving as a seed layer, a magnesium oxide (MgO) film of 10 nm thick serving as an orientation control underlayer 101, an FePt ordered alloy of 6 nm thick serving as a recording layer, and a nitride-containing carbon film of 2.0 nm thick serving as a protective film 103 were sequentially formed on a glass substrate of 65 mm in diameter in order to produce a base medium.

After particles adhering to the surface of the base medium were washed down through pure water washing, a resist pattern 106 was formed on the surface of the base medium using a nano-imprint method. The resist pattern 106 has a region of bit patterns that have a pitch of 25 nm, and a region of servo patterns. The resist film thickness of an upper part of the resist pattern was 38 nm, and the resist film thickness of a bottom portion thereof was 7 nm.

A fabrication method will be described below in conjunction with FIG. 2A to FIG. 2G. The concavo-convex pattern 106 of a resist like the one shown in FIG. 2A is formed on the surface of the base medium through nano-imprint. First, a residual resist film remaining on the bottoms of concave parts of the imprinted resist were removed by performing reactive ion etching with oxygen. At this time, the carbon protective film 103 formed on the surface of the recording layer was also removed. This results in the sectional structure shown in FIG. 2B.

Thereafter, the resist pattern 106 was transferred to the recording layer. The recording layer formed with the FePt alloy film was cut out by performing ion beam etching with argon. The etching was ceased when the orientation control underlayer 101 was a bit cut out. This results in the sectional structure shown in FIG. 2C. The ion beam etching was performed using an ECR ion source for a processing time of 8 sec under the conditions that an acceleration voltage was 300 V and a beam incident angle was a perpendicular with respect to the film surface. The resist left on the surface of the recording layer and the carbon protective film 103 were removed by performing reactive ion etching with hydrogen, whereby the sectional structure shown in FIG. 2D was obtained. The reactive ion etching was performed using inductively coupled plasma for a processing time of 120 sec under the conditions that a hydrogen flow rate was 150 sccm, a gas pressure was 5 Pa, and a power was 200 W.

Thereafter, a carbon film of approximately 20 nm thick was formed using a sputtering method in order to backfill grooves formed in the magnetic film. The carbon film was etched back and planarized through sputter etching with argon. When the thickness of the carbon film became approximately 5 nm, the sputter etching was ceased and switched into ion beam etching with argon.

The etching back was carried on until the state shown in FIG. 2E proceeds to a state in which the recording layer finally, as shown in FIG. 2F, comes out to the surface of the medium. At this time, overetching occurred by a time it takes to cut out the FePt alloy film of approximately 1 nm thick. Using an ECT ion source, ion beam etching was performed under the conditions that an acceleration voltage was 500 V and a beam incident angle was a perpendicular with respect to the film surface. Owing to the overetching caused with an ion beam of argon, the surface of the FePt alloy magnetic film was turned into amorphous to produce an amorphous magnetic film 105. A film thickness to be turned into amorphous can be controlled by modifying conditions for overetching.

Finally, a nitride-containing carbon film of 2.5 nm thick was formed as the protective film 103 using a sputtering method, and the medium was taken out of a vacuum chamber (FIG. 2G). A lubrication film of 1 nm thick was applied to the surface of the protective film, and tape cleaning was performed in order to finish the bit-patterned medium.

In order to check the structure of the fabricated bit-patterned medium, the section of the medium was observed using a high-density transmission electron microscope. The layered construction of the section was nearly as shown in FIG. 1. The crystalline magnetic film (recording layer) 102 of a FePt alloy was seen to have grown as columnar grains. Further, the amorphous magnetic film 105 of 1 nm thick was seen to be produced on the crystalline magnetic film (recording layer) 102. The amorphous carbon backfilling film 104 was seen to exist among the bit patterns formed on the magnetic film. The carbon protective film 103 was seen to be nearly flatly formed on the surface of the medium.

The superficial shape of the medium was evaluated using an atomic force microscope (AFM). The average roughness (Ra) obtained by scanning the bit pattern region with a visual field of 1 μm was 0.42 nm. Production of a smooth surface was verified.

Thereafter, a spin-stand tester was used to evaluate recording and reproduction performances. During recording, in addition to a magnetic field induced by a recording head, heat was locally applied using a laser in order to facilitate inversion. A reproduction head was used to produce a two-dimensional map of a bit pattern. It was verified that all bits were recorded without any error.

Further, a corrosion resistance test was conducted on the bit-patterned medium. After the medium was left intact for 96 hours in an atmosphere of 80° C. in temperature and 90% in humidity, the number of corroded points was counted and regarded as an index of corrosion resistance. The number of corroded points on the medium of the present embodiment was five per square centimeter (cm²). The medium has proved superior in corrosion resistance.

As mentioned above, according to the present embodiment, since an amorphous magnetic film whose compositional elements are identical to those of a crystalline magnetic film serving as a recording layer is formed on the crystalline magnetic film, the spacing between a head and a medium can be minimized. In addition, a patterned medium that is superior in corrosion resistance and a fabrication method thereof can be provided. The present embodiment has proved effective even in a bit-patterned medium.

### Third Comparative Example

A bit-patterned medium of the present comparative example was fabricated using a base medium nearly identical to that of the third embodiment. A sole difference from the base medium employed in the third embodiment lies in that the thickness of an FePt alloy film is set to 5 nm.

For processing of the medium, a process nearly identical to that for the third embodiment was adopted. A sole difference lies in that an acceleration voltage for ion beam etching with argon adopted in order to finish etching back of carbon that is used as a backfill is set to 150 V. The ion beam etching was ceased without overetching of the FePt alloy film. Finally, a nitride-containing carbon film of 2 nm thick was formed as a protective film, a lubrication film of 1 nm thick was applied to the surface of the protective film, and tape cleaning was carried out.

The fabricated bit-patterned medium was evaluated using the same method as that employed in the third embodiment. The section of the medium was observed using a high-resolution transmission electron microscope. A crystalline magnetic film of an FePt alloy was, similarly to that in the third embodiment, seen to have grown as columnar grains. However, an amorphous magnetic film did not exist on the crystalline magnetic film. The medium had the structure of having a carbon protective film directly layered on the crystalline magnetic film.

The superficial shape of the medium was evaluated using an atomic force microscope (AFM). The average roughness (Ra) obtained by scanning the surface of the medium with a visual field of 1 μm was 1.68 nm. Compared with the third embodiment, the surface roughness was found to have increased.

For evaluation of recording and reproduction performances using a spin-stand tester, similarly to that in the third embodiment, recording was performed with the assistance of a laser, and a two-dimensional map of a bit pattern was produced using a reproduction head. Several error-stricken points were observed. Since the spacing between the head and medium was widened, a recording resolution was thought to have decreased.

Further, a corrosion resistance test was conducted. The number of corroded points on the medium of the comparative example was 156 per square centimeter (cm²). This demonstrates that compared with the third embodiment, the present comparative example is inferior in corrosion resistance. Since the coating ability of the carbon protective film becomes insufficient because of an increase in the surface roughness of the recording layer, and the surface of the recording layer is inhomogeneous, corrosion is presumably likely to occur.

### Fourth Comparative Example

A bit-patterned medium of the present comparative example was fabricated using a base medium nearly identical to that of the third comparative example. A sole difference from the base medium employed in the third embodiment lies in that an iron tantalum zirconium (FeTaZr) alloy magnetic film of 1 nm thick is formed on an FePt alloy film. The FeTaZr alloy magnetic film is an amorphous soft magnetic film. For processing of the medium, the same process as that in the third comparative example was adopted.

The fabricated bit-patterned medium was evaluated using the same method as that employed in the third embodiment. The superficial shape of the medium was evaluated using an atomic force microscope (AFM). The average roughness (Ra) obtained by scanning the surface of the medium with a visual field of 1 μm was 0.69 nm. The surface of the medium was found to be a relatively smooth.

For evaluation of recording and reproduction performances using a spin-stand tester, similarly to the third embodiment, recording was performed with the assistance of a laser, and a two-dimensional map of a bit pattern was produced using a reproduction head. No error was observed.

A corrosion resistance test was conducted. The number of corroded points on the medium of the present comparative example was 149 per square centimeter (cm²). This demonstrates that compared with the third embodiment, the present comparative example is inferior in corrosion resistance. The surface roughness of the recording layer is not as large as that of the third embodiment. Owing to the layering of magnetic films that are different from each other in terms of compositional elements, an electric potential is generated between the magnetic films. This presumably facilitates corrosion. For improvement of corrosion resistance, not only the structure of a magnetic film to be layered near the surface of the medium but also a combination of compositional elements has significant meanings.

1. A patterned medium, wherein:
a recording layer includes one layer of a crystalline magnetic film or a plurality of layers of crystalline magnetic films, and a magnetic film of an amorphous structure located on the outermost surface of the crystalline magnetic films; and
the compositional elements of the magnetic film of the amorphous structure are identical to the compositional elements of the crystalline magnetic film located immediately under the magnetic film.

2. A patterned medium comprising:
a substrate;
a recording layer formed on a first region of the substrate; and
a backfilling film formed on the perimeter of the recording layer, wherein
the recording layer includes a crystalline magnetic film and an amorphous magnetic film having the surface of the crystalline magnetic film turned into amorphous.

3. The patterned medium according to claim 2, wherein the patterned medium is a discrete track medium.

4. The patterned medium according to claim 2, wherein the patterned medium is a bit-patterned medium.

5. The patterned medium according to claim 2, wherein the crystalline magnetic film is a multilayer film having a plurality of crystalline magnetic films layered.

6. The patterned medium according to claim 2, wherein:
a soft magnetic underlayer, a seed layer, and an orientation control underlayer are formed in that order from the side of the substrate between the substrate and recording layer; and
a protective layer is formed over the recording layer and backfilling film.

7. A fabrication method of the patterned medium as set forth in claim 1, wherein:
ions are irradiated to the outermost surface of the crystalline magnetic films in order to make the surface of the magnetic film of the crystalline structure amorphous.

8. A fabrication method of a patterned medium comprising:
sequentially forming a crystalline magnetic film and a protective film on a substrate;
forming a resist pattern on the protective film;
transferring the resist pattern to the crystalline magnetic film and protective film alike;
removing the resist pattern and protective film that remain on the substrate;
forming a backfilling film so as to cover the crystalline magnetic film to which the resist pattern has been transferred; and
forming an amorphous magnetic film by removing the backfilling film and making the surface of the crystalline magnetic film amorphous.

9. The fabrication method of a patterned medium according to claim 8, wherein the surface of the crystalline magnetic film is turned into amorphous by irradiating ions.

10. The fabrication method of a patterned medium according to claim 9, wherein the resist pattern is formed using a nano-imprint method.
